(19) United States
(12) Patent Application Publication
(10) Pub. No.: US 2012/0160543 A1
(43) Pub. Date: Jun. 28, 2012

(54) CIRCUIT BOARD TO BE ATTACHED TO SUPPORT THROUGH THERMOPLASTIC STAKING

(75) Inventors: Masaya NAKANISHI, Toyohashi-shi (JP); Yasuhito TANABE, Chita-gun (JP); Hidemitsu WATANABE, Kariya-shi (JP)

(73) Assignee: DENSO CORPORATION, Kariya-city (JP)

(21) Appl. No.: 13/332,925

(22) Filed: Dec. 21, 2011

(30) Foreign Application Priority Data
Dec. 23, 2010 (JP) 2010-286822

(51) Int. Cl. H05K 1/02

(52) U.S. Cl. 174/250

(57) ABSTRACT

A circuit board to be attached to a support such as a case body is provided. The circuit board has formed therein a mounting hole which is so designed as to permit a thermally deformable stud to protrude through the mounting hole and also to be thermoplastically staked to mount the board to the support. A layer is printed on the board by means of silk screen printing at a distance from the mounting hole. In a case where a moisture-proof and insulating material is applied over a surface of the board, the printed layer servers to block a flow of the moisture-proof and insulating material into the mounting hole. This avoids a reduction in strength of fastening the board to the support. The printed layer may also be used in visually inspecting a failure in thermoplastic staking to mount the board to the support.

### CROSS REFERENCE TO RELATED DOCUMENT

The present application claims the benefit of priority of Japanese Patent Application No. 2010-286822 filed on Dec. 23, 2010, the disclosure of which is incorporated herein by reference.

### BACKGROUND OF THE INVENTION

1 Technical Field

This disclosure relates generally to a circuit board to be attached to a support such as a case body by means of that moplastic staking.

2 Background Art

Japanese Patent First Publication No. 8-32214 teaches a technique of applying a watery flux over the surface of a circuit board, soldering electronic components onto the circuit board, washing the circuit board to remove the flux, applying a moisture-proof material (also called a damp-proof material) onto the circuit board, and drying it. Japanese Patent First Publication No 2000-313346 discloses a circuit case in which a circuit board is secured to a synthetic resin-made case body by means of thermoplastic riveting or staking. Specifically, the circuit board has mounting holes formed therein. The base body has thermally deformable studs formed thereon. The circuit board is mounted on the base body with the mounting holes fit in the studs. The heads of the studs are thermally compressed to lock the circuit board and the case body together.

When the circuit board coated with the moisture-proof material, as disclosed in the former publication, is secured to the case body using the thermoplastic staking technique, as taught in the latter publication, the problem is encountered in that the strength of fastening the circuit board to the case body is reduced. For instance, when applied over the circuit board, the moisture-proof material may drip into the mounting hole, thereby resulting in a reduction in strength in fastening the circuit board to the case body. The amount of the moisture-proof material dripping into the mounting hole may be decreased by increasing the size of the circuit board, but it will also require increasing the size of the case body, thus resulting in an increase in production cost of the circuit board and the case body. The increase in size of the circuit board may also lead to deformation or breakage thereof.

The attachment of the circuit board to the case body is, as described above, achieved by thermoplastically staking the heads of the resin-made studs, so that the opening ends of the mounting holes will be closed by the compressed heads of the studs. It is, therefore, difficult to visually inspect a failure in the thermoplastic staking arising from misalignment of a staking punch or dimension tolerances of the mounting holes and the studs.

### SUMMARY

It is therefore an object to provide an improved structure of a circuit board which is designed to ensure a high degree of strength in fastening the circuit board to a support such as a case body.

It is another object to provide an improved structure of a circuit board which facilitates the ease with which a failure in thermoplastic staking is visually inspected.

According to one aspect of an embodiment, there is provided a circuit board which is to be attached to a support such as a case body. The circuit board comprises: (a) a board; (b) a mounting hole formed in the board, the hole being so designed as to permit a thermally deformable member to protrude through the hole and also to be thermoplastically staked to mount the board to the support; and (c) a layer printed on the board by means of silk screen printing. The printed layer is located around the mounting hole.

In a case where a moisture-proof and insulating material is applied over a surface of the board, a thickness of the printed layer serves as a shield to block a flow of the moisture-proof and insulating material into the mounting hole. This avoids a reduction in strength in fastening the board to the support which arises from dripping of the moisture-proof and insulating material into the mounting hole. Additionally, the printed layer is located around the mounting hole, thus enabling an operator to visually perceive a positional relation between the thermoplastically staked member fit in the mounting hole and the printed layer. The printed layer may, therefore, be used as an inspection basis in visually inspecting a failure in thermoplastic staking to mount the board to the support.

In the preferred mode of the embodiment, the printed layer is so shaped as to surround a circumference of the mounting hole. A moisture-proof and insulating material is applied over an area of the board outside the printed layer. Specifically, the printed layer serves to block the flow of the moisture-proof and insulating material inside it, thereby ensuring the strength of attachment of the circuit board to the support.

The thermally deformable member is made of resin. The printed layer is so located as to avoid physical interference with the thermally deformable member after being thermoplastically staked, thus ensuring the stability in thermoplastically staking the thermally deformable member.

A component mark which represents a location where an electronic component is to be mounted on the board and on which at least one of a part name of the electronic component or an identification code specifying the kind of the electronic component is printed may be formed on the board by silk screen printing along with the layer.

The printed layer may be of a circular ring shape which surrounds the circumference of the mounting hole. This permits the printed layer to be minimized in area, thus resulting in a decrease in production cost of the circuit board.

The circuit board may also include a second circular ring shaped layer printed around the circumference of the mounting hole. Specifically, the printed layer and the second circular ring shaped layer work as a double-walled shield to block the flow of the moisture-proof and insulating material into the mounting hole.

The printed layer may be located coaxially with the mounting hole. This facilitates the ease with which an operator visually perceives the misalignment or undesirable deformation of the thermoplastically staked member based on a positional relation between the printed layer and the thermoplastically staked member.

The circuit board may also include a plurality of walls printed on the board by silk screen printing. The walls radiate from the printed layer. The walls serve to add an additional surface area to the printed layer to create a degree of surface tension of the moisture-proof and insulating material which prevents it from flowing inside the printed layer.

The circuit board may further include a shield wall printed on the board by silk screen printing. The shield wall extends outside the printed layer, thereby further decreasing the possibility that the moisture-proof and insulating material drips into the mounting hole.

The printed layer may be made up of a laminate of sublayers which are respectively formed by silk screen printing. This facilitates the ease of increasing a total thickness of the printed layer to a desired value.

### BRIEF DESCRIPTION OF THE DRAWINGS

The present invention will be understood more fully from the detailed description given hereinbelow and from the accompanying drawings of the preferred embodiments of the invention, which, however, should not be taken to limit the invention to the specific embodiments but are for the purpose of explanation and understanding only.

In the drawings:

FIG. 1 is a partially sectional view which illustrates a printed circuit assembly attached to a case body according to the first embodiment;

FIG. 2 is a plane view of FIG. 1;

FIG. 3 is a flowchart of a sequence of steps of producing the printed circuit assembly of FIGS. 1 and 2;

FIG. 4 is a partial plane view which illustrates a mounting hole and its surrounding area before a mounting stud protruding from a casing body into the mounting hole is staked thermoplastically;

FIG. 5 is a partially longitudinal sectional view of FIG. 4;

FIG. 6 is a partially longitudinal sectional view which illustrates a circuit board assembly after a mounting stud is thermally staked;

FIGS. 7(a) and 7(b) are plane views which demonstrate examples of inspection of a thermoplastically compressed head of a mounting stud using a printed mounting hole surrounding layer for the installation of a printed circuit assembly to a case body;

FIGS. 8(a) and 8(b) are plane views which demonstrate other examples of inspection of a thermoplastically compressed head of a mounting stud using a printed mounting hole surrounding layer for the installation of a printed circuit assembly to a case body;

FIG. 9 is a partially plane view which illustrates a first modification of a printed circuit board;

FIG. 10 is a longitudinal sectional view of FIG. 9;

FIG. 11 is a longitudinal sectional view of the printed circuit board of FIG. 9 after a head of a mounting stud is thermoplastically staked;

FIG. 12 is a partially plane view which illustrates a second modification of a printed circuit board;

FIG. 13 is a partially plane view which illustrates a third modification of a printed circuit board;

FIG. 14(a) is a partially plane view which illustrates a fourth modification of a printed circuit board; and

FIG. 14(b) is a partially plane view which illustrates a fifth modification of a printed circuit board.

### DESCRIPTION OF THE PREFERRED EMBODIMENTS

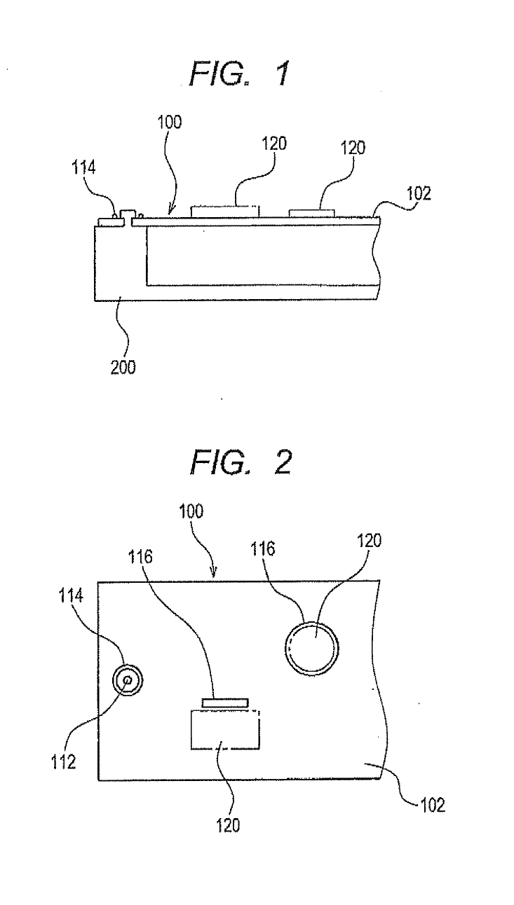

Referring to the drawings, wherein like reference numbers refer to like parts in several views, particularly to FIG. 1, there is shown a printed circuit assembly 100 which is secured to a case body 200 by means of thermoplastic staking (also called heat staking or riveting) according to an embodiment of the invention. FIG. 1 is a partially sectional view of the printed circuit assembly 100 attached to the case body 200. FIG. 2 is a plane view of FIG. 1.

The printed circuit assembly 100 is equipped with a printed circuit board 102 which is fixed to the case body 200 (i.e., a support) using the thermoplastic staking technique. The printed circuit board 102 has mounting holes 112 (only one is shown for the brevity of illustration). The printed circuit assembly 100 also includes a printed mounting hole surrounding layer 112 formed around the mounting hole 112, and printed component marks 116 each of which represents the location on the printed circuit board 102 where an electronic component 120 is to be mounted and on each of which at least one of a part name of the electronic component 120 or an identification code specifying the type of the electronic component 120 is printed. The printed mounting hole surrounding layer 112 and the printed component marks 116 are formed on the printed circuit board 102 before the electronic components 120 are populated.

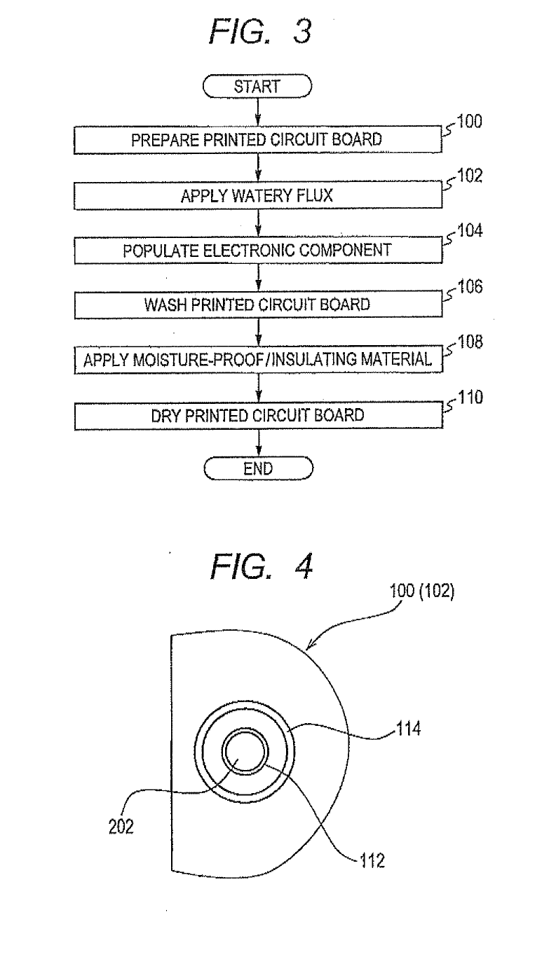

FIG. 3 is a flowchart of a sequence of steps of producing the printed circuit assembly 100 using the printed circuit board 102 and the electronic components 120.

First, in step 100, the printed circuit board 102 on which connecting wires for the electronic components 120, the printed mounting hole surrounding layer 114, and the printed component marks 116 are formed and in which the mounting hole 112 is drilled is prepared.

The routine proceeds to step 102 wherein a watery flux is applied over the whole of one of major surfaces of the printed circuit board 102 on which the electronic components 120 are to be soldered.

The routine proceeds to step 104 wherein the electronic components 120 are placed at predetermined locations on the printed circuit board 102 and then soldered.

The routine proceeds to step 106 wherein the printed circuit board 102 is washed with water to remove the watery flux therefrom.

The routine proceeds to step 108 wherein a moisture-proof and insulating material 130, as will be described later, is applied to the surface of the printed circuit board 102. The routine proceeds to step 110 wherein the printed circuit board 102 is dried. This completes the printed circuit assembly 100 wherein the electronic components 120 are mounted on the printed circuit board 102.

The installation of the printed circuit assembly 100 to the case body 200 is achieved by inserting a cylindrical mounting pin or stud 202 into the mounting hole 112 of the printed circuit board 102 and thermally softening and deforming the head of the mounting stud 202 to lock the printed circuit assembly 100 and the case body 200 together using the so-called thermoplastic staking technique. The mounting stud 202 may be made from resin.

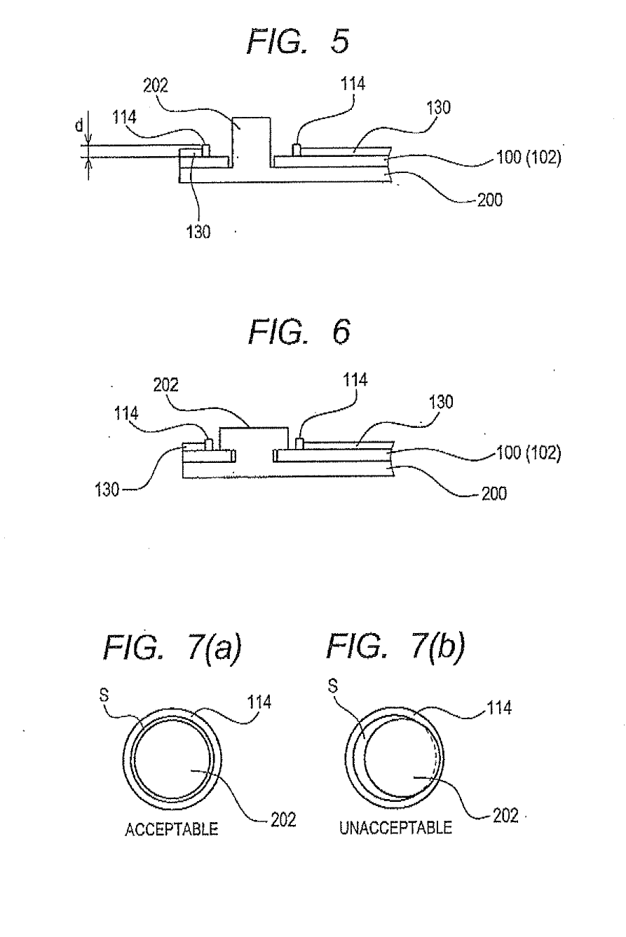

The structure of the printed circuit assembly 100, especially the shape and layout of the printed mounting hole surrounding layer 114 will be described below with reference to FIGS. 4, 5, and 6. FIG. 4 is a partial plane view which illustrates the mounting hole 112 and its surrounding area before the stud 202 protruding from the casing body 200 into the mounting hole 112 is staked thermally. FIG. 5 is a partially longitudinal sectional view of FIG. 4. FIG. 6 is a partially longitudinal sectional view which illustrates the circuit board assembly 100 after the mounting stud 202 is thermally staked.

The printed mounting hole surrounding layer 114 is, as can be seen from FIGS. 4 and 5, of a circular ring shape which is coaxial with the circular mounting hole 112. The printed mounting hole surrounding layer 114 extends around the circumference of the mounting hole 12. The application of the moisture-proof and insulating material 130 in step 108 is achieved over an area of the printed circuit board 102 outside the printed mounting hole surrounding layer 114 and the mounting hole 112. The printed mounting hole surrounding layer 114 is formed in the silk screen printing to have a given thickness d, as illustrated in FIG. 5, which serves to block the intrusion of the moisture-proof and insulating material 130 inside the mounting hole surrounding layer 114 and the mounting hole 112.

The printed mounting hole surrounding layer 114 is, as illustrated in FIG. 6, designed to have a size great enough to embrace is around the compressed head of the mounting stud 202 after being deformed thermoplastically. In other words, the printed mounting hole surrounding layer 114 has an inner diameter greater than an outer diameter of the compressed head of the mounting stud 202, thereby eliminating the mechanical interference with the thermoplastic staking of the mounting stud 202. The printed mounting hole surrounding layer 114 is formed in the silk screen printing along with printed component marks 116, thus eliminating the need for an additional steps of forming the printed mounting hole surrounding layer 114.

As described above, the silk screen-printed mounting hole surrounding layer 114 serves as a shield wall having a thickness great enough to block the flow of the moisture-proof and insulating material 130 to around or into the mounting hole 112 when the moisture-proof and insulating material 130 is applied to the printed circuit board 102, thus avoiding the interference of the moisture-proof and insulating material 130 with the thermoplastic staking of the mounting stud 202. This alleviates the problem, as encountered by the prior art discussed in the introductory part of this application, that when the printed circuit assembly 100 is secured to the case body 114 by thermoplastically staking the mounting stud 202, the moisture-proof and insulating material 130 entering the mounting hole 112 or staying near the mounting hole 112 melts and contributes to a reduction in strength of fastening the printed circuit assembly 100 to the case body 200. The printed mounting hole surrounding layer 114 is of a circular ring shape, thus permitting it to have a minimum volume required to shield an area of the surface of the printed circuit board 102 where the head of the mounting stud 202 is thermoplastically staked from the interference with the moisture-proof and insulating material 130. This minimizes the production cost of the printed circuit board 102.

The printed mounting hole surrounding layer 114 is located coaxially with the mounting hole 112, thereby facilitating the ease with which an operator visually perceives the misalignment or undesirable deformation of the thermoplastically compressed head of the mounting stud 202 based on a positional relation between the printed mounting hole surrounding layer 114 and the head of the mounting stud 202.

FIGS. 7(a) and 7(b) demonstrate examples of inspection of the thermoplastically compressed head of the mounting stud 202 using the printed mounting hole surrounding layer 114 for the installation of the printed circuit assembly 100 to the case body 200. The printed mounting hole surrounding layer 114 is, as described above, configured to have the inner diameter slightly greater than the outer diameter of the thermoplastically compressed head of the mounting stud 202. FIG. 7(a) illustrates the case where an air gap S between the inner circumference of the printed mounting hole surrounding layer 114 and the outer circumference of the head of the mounting stud 202 is kept constant. The installation of the printed circuit assembly 100 to the case body 200 is, therefore, determined as being acceptable. FIG. 7(b) illustrates the case where the compressed head of the mounting stud 202 partially overlaps the printed mounting hole surrounding layer 114. The installation of the printed circuit assembly 100 to the case body 200 is, therefore, determined as being unacceptable.

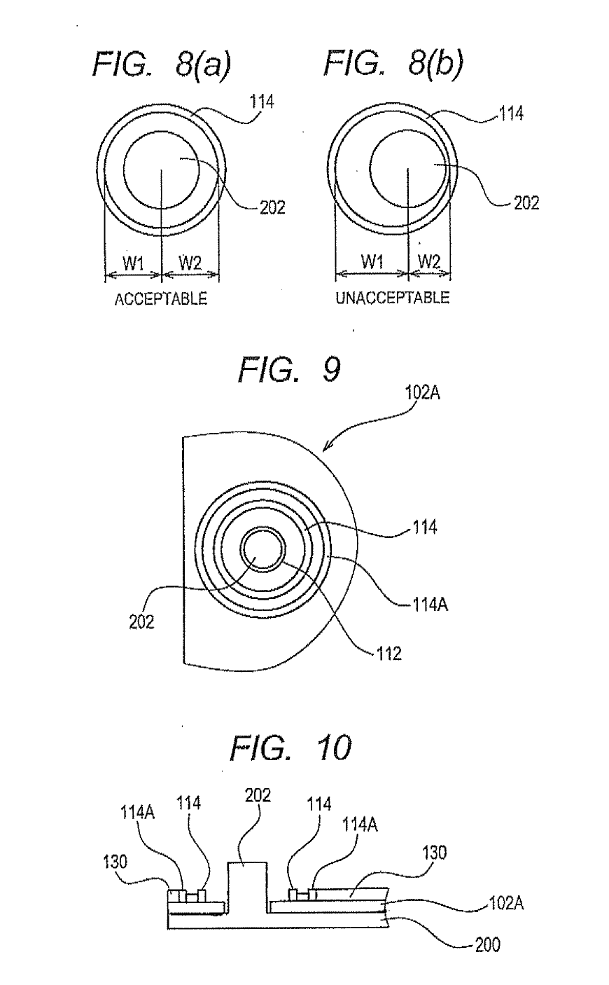

FIGS. 8(a) and 8(b) demonstrate other examples of inspection of the thermoplastically compressed head of the mounting stud 202 using the printed mounting hole surrounding layer 114 for the installation of the printed circuit assembly 100 to the case body 200. The printed mounting hole surrounding layer 114 may be so designed as to avoid the interference with the thermoplastically compressed head of the mounting stud 202. FIG. 8(a) illustrates the case where a difference between distances W1 and W2 between the center of the head of the mounting stud 202 and diametrically opposed points on the inner circumference of the printed mounting hole surrounding layer 114 lies within an allowable range. The installation of the printed circuit assembly 100 to the case body 200 is, therefore, determined as being acceptable. FIG. 8(b) illustrates the case where a difference between distances W1 and W2 lies out of the allowable range. The installation of the printed circuit assembly 100 to the case body 200 is, therefore, determined as being unacceptable. The diametrically opposed points are preferably selected to be aligned with the direction in which the compressed head of the mounting stud 202 is shifted. The determination in either case may be made based on comparison of one of the distances W1 and W2 with a given reference range.

Specifically, the printed mounting hole surrounding layer 114 serves as an inspection basis for use in visually inspecting whether the eccentricity of the thermoplastically compressed head of the mounting stud 202 is acceptable or not, that is, whether the attachment of the printed circuit assembly 100 to the case body 200 is defective or not and thus enhances the ease of such visual inspection.

While the present invention has been disclosed in terms of the preferred embodiment in order to facilitate better understanding thereof, it should be appreciated that the invention can be embodied in various ways without departing from the principle of the invention. Therefore, the invention should be understood to include all possible embodiments and modifications to the shown embodiments which can be embodied without departing from the principle of the invention as set forth in the appended claims.

For instance, a plurality of coaxial circular layers may be formed around the mounting hole 112 instead of the single mounting hole surrounding layer 114.

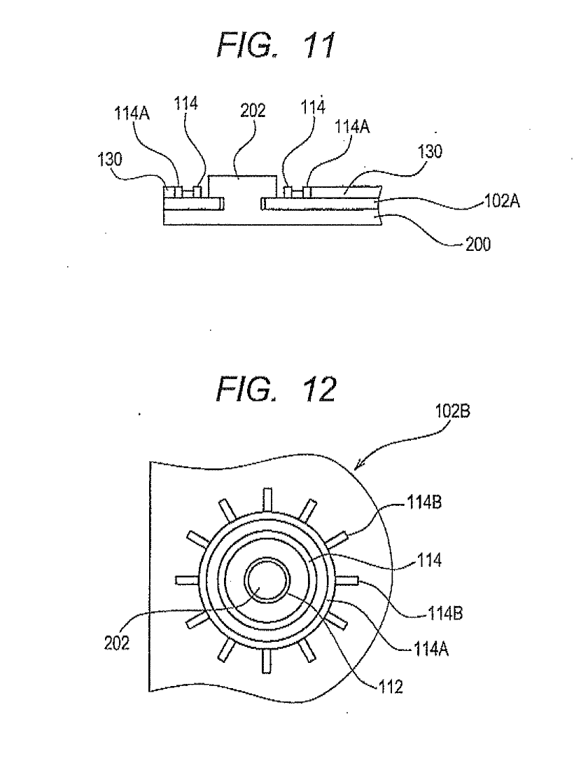

FIG. 9 illustrates a printed circuit board 102A that is a modification of the printed circuit board 102 of FIG. 1. The mounting stud 202, as illustrated, is not yet deformed thermoplastically. FIG. 10 is a longitudinal sectional view of FIG. 9. FIG. 11 is a longitudinal sectional view of the printed circuit board 102A after the head of the mounting stud 202 is thermoplastically staked. The printed circuit board 102A has two circular ring walls: the first printed mounting hole surrounding layer 114 and the second printed mounting hole surrounding layer 114A. The first printed mounting hole surrounding layer 114 is the same as the one in FIG. 1. The second printed mounting hole surrounding layer 114A is greater in diameter than the first printed mounting hole surrounding layer 114 and located coaxially therewith.

Even when the amount of the moisture-proof and insulating material 130 is excessive, so that it flows over the second printed mounting hole surrounding layer 114A, the first printed mounting hole surrounding layer 114 works to block more intrusion thereof, especially into the mounting hole 112.

Each of the first and second printed mounting hole surrounding layers 114 and 114A may be designed to be of a non-circular shape.

FIG. 12 illustrates the printed circuit board 102B that is a modification of the printed circuit board 102A of FIGS. 9 to 11. Specifically, the printed circuit board 1023 has a plurality of walls 114B radiating from the center of the mounting hole 112. The walls 114B are of a rectangular shape and extend from the outer circumference of the second printed mounting hole surrounding layer 114 at regular intervals away from each other. The walls 1148 are formed in the silk screen printing simultaneously along with the first and second printed mounting hole surrounding layers 114 and 114A. The walls 114B serve to add an additional surface area to a total surface area of the first and second printed mounting hole surrounding layers 114 and 114A to create a degree of surface tension of the moisture-proof and insulating material 130 which prevents it from flowing inside the first printed mounting hole surrounding layer 114. The printed circuit board 102 of FIG. 4 may be designed to have the walls 114B extending directly from the outer circumference of the printed mounting hole surrounding layer 114.

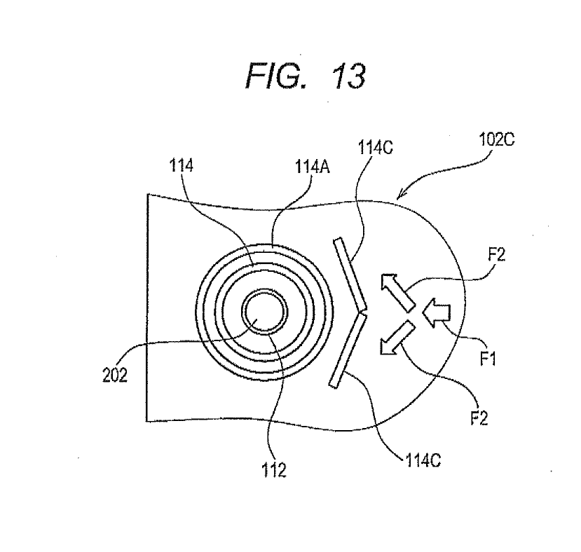

FIG. 13 illustrates the printed circuit board 102C that is a modification of the printed circuit board 102A of FIGS. 9 to 11. Specifically, the printed circuit board 102C has two walls 114C extending outside the second printed mounting hole surrounding layer 114A. The walls 114C are formed in the silk screen printing simultaneously along with the first and second printed mounting hole surrounding layers 114 and 114A and placed in contact abutment at ends thereof with each other extend at an obtuse angle in opposite direction. The contact ends of the walls 114C lie on an extension of a flow of the moisture-proof and insulating material 130. The walls 1140, therefore, serve as a shield the first and second printed mounting hole surrounding layers 114 and 114A from the flow of the moisture-proof and insulating material 130 and also as a flow splitter which splits the flow of the moisture-proof and insulating material 130, as indicated by an arrow F1, into two streams, as indicated arrows F2. Specifically, the walls 114C direct the streams F2 of the moisture-proof and insulating material 130 away from the mounting hole 112, thereby minimizing the amount of the moisture-proof and insulating material 130 reaching the second printed mounting hole surrounding layer 114A. The printed circuit board 102 of FIG. 4 may be designed to have the walls 114C extending outside the printed mounting hole surrounding layer 114.

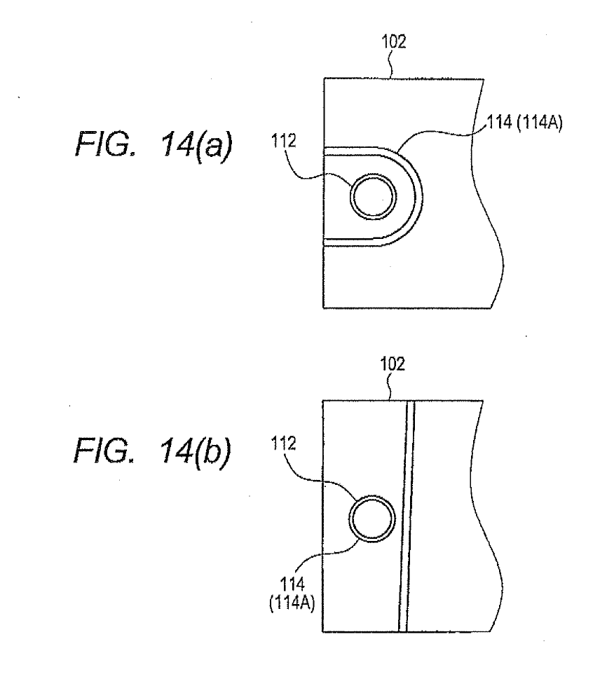

Each of the first and second printed mounting hole surrounding layers 114 and 114A needs not necessarily be circular in shape. FIGS. 14(a) and 14(b) illustrate modifications of the printed mounting hole surrounding layer 114. The printed mounting hole surrounding layer 114 of FIG. 14(a) is of a U-shape and extends at ends thereof from and to the edge of the printed circuit board 101 so as to embrace the mounting hole 112 completely. The printed mounting hole surrounding layer 114 of FIG. 14(b) is a straight wall which passes near the mounting hole 112 and traverses the width of the printed circuit board 102 to block the flow of the moisture-proof and insulating material 130 into the mounting hole 112.

Each of the first and second printed mounting hole surrounding layers 114 and 114A and the walls 114B and 1140 may be made up of a laminate of multiple sublayers which are respectively printed by the silk screen printing. This facilitates the ease with which the thickness of each of the first and second printed mounting hole surrounding layers 114 and 114A and the walls 114E and 114C is increased to a desired value.

What is claimed is:

1. A circuit board to be attached to a support comprising:
a board;
a mounting hole formed in the board, the hole being so designed as to permit a thermally deformable member to protrude through the mounting hole and also to be thermoplastically staked to mount the board to the support; and
a layer printed on the board by means of silk screen printing, the printed layer being located around the mounting hole.

2. A circuit board as set forth in claim 1, wherein the printed layer is so shaped as to surround a circumference of the mounting hole, and wherein a moisture-proof and insulating material is applied over an area of the board outside the printed layer,

3. A circuit board as set forth in claim 1, wherein the thermally deformable member is made of resin, and wherein the printed layer is so located as to avoid physical interference with the thermally deformable member after being thermoplastically staked.

4. A circuit board as set forth in claim 1, wherein a component mark which represents a location where an electronic component is to be mounted on the board and on which at least one of a part name or an identification code specifying the electronic component is printed is formed on the board by silk screen printing along with the layer.

5. A circuit board as set forth in claim 1, wherein the printed layer is of a circular ring shape which surrounds a circumference of the mounting hole.

6. A circuit board as set forth in claim 5, further comprising a second circular ring shaped layer printed around the circumference of the mounting hole.

7. A circuit board as set forth in claim 5, wherein said printed layer is located coaxially with the mounting hole.

8. A circuit board as set forth in claim 5, further comprising a plurality of walls printed on the board by silk screen printing, the walls radiating from the printed layer.

9. A circuit board as set forth in claim 5, further comprising a shield wall printed on the board by silk screen printing, the shield wall extending outside the printed layer.

10. A circuit board as set forth in claim 1, wherein the printed layer is made up of a laminate of sublayers which are respectively formed by silk screen printing.
